(19) United States
(12) Patent Application Publication
(10) Pub. No.: US 2026/0121653 A1
(43) Pub. Date: Apr. 30, 2026

(54) Low computational complexity modulo sampler based on level crossing side information

(71) Applicant: YEDA Research and Development Co. Ltd., Rehovot (IL)

(72) Inventors: Yonina Eldar, Rehovot (IL); Shaik Basheeruddin Shah, Abu Dhabi (AE); Nimrod Glazer, Rehovot (IL); Shlomi Savariego, Rehovot (IL)

(21) Appl. No.: 19/420,866

(22) Filed: Dec. 16, 2025

Related U.S. Application Data
(63) Continuation-in-part of application No. PCT/IB2024/061994, filed on Nov. 28, 2024.

(30) Foreign Application Priority Data
Dec. 3, 2023 (IL) 309058

(51) Int. Cl. H03M 1/12

(52) U.S. Cl. CPC H03M 1/1245

(57) ABSTRACT

An apparatus (20) for sampling signals includes a modulo circuit (24), an Analog to Digital Converter (ADC—28) and processing circuitry (32). The modulo circuit is configured to receive an analog signal (40), and to derive from the analog signal (i) an analog folded signal (48) whose amplitude is limited to a predefined dynamic range, and (ii) side information (36) indicative of instances in which the analog signal transitions between levels corresponding to odd integer multiples of boundaries specifying the dynamic range. The ADC is configured to sample the analog folded signal to produce a digital folded signal (52). The processing circuitry is configured to generate a digital unfolded signal (44), which represents the analog signal both within and outside the dynamic range, based on the digital folded signal and on the side information, and to output the digital unfolded signal.

### CROSS-REFERENCE TO RELATED APPLICATIONS

This application is a continuation-in-part of PCT Application PCT/IB2024/061994, filed Nov. 28, 2024, which claims priority from Israel Patent Application 309,058, filed Dec. 3, 2023. The disclosures of these related applications are incorporated herein by reference.

### TECHNICAL FIELD

Embodiments described herein relate generally to modulo sampling, and particularly to methods and systems for low computational complexity modulo sampling based on level crossing side information.

### BACKGROUND

In various systems and applications, an analog signal is digitized before being processed in a digital form. Digitization is typically carried out using an Analog to Digital Converter (ADC), which samples the analog signal and quantizes the samples to produce a sequence of digital samples.

The range of analog values between specified minimal and maximal analog values that the ADC can digitize without clipping is referred to as the ADC's “dynamic range.” Clipping may distort the signal significantly, even to an unacceptable level, and therefore should be avoided.

One way to handle analog signals exceeding the ADC's dynamic range is to apply a non-linear operation to the analog signal before being processed by the ADC, and recover the full range samples after the ADC processing. The non-linear operation aims to restrict the amplitude of the input analog signal to the dynamic range. A sampler of this sort, which applies a modulo (wrapping) non-linear operation is referred to herein as a “modulo sampler.”

Modulo sampling is known in the art. For example, in a paper entitled “Robust Unlimited Sampling Beyond Modulo” in preprint arXiv:220614656 (2022), the authors propose a generalized flexible nonlinear operator. Moreover, by carefully choosing the operator parameters, clipping, modulo, and companding can be seen as special cases of the nonlinear operation. The authors propose a robust algorithm, referred to as “Beyond Bandwidth Residual Reconstruction” (B²R²), for recovering the true signal from the nonlinear samples.

Anther modulo sampling approach has been presented under the title “LASSO-BASED FAST RESIDUAL RECOVERY FOR MODULO SAMPLING” in the 2023 IEEE international conference on Acoustic, Speech and Signal processing, 4-10 June, Rhodes Island, Greece. The algorithm proposed in this work uses iterative sparse recovery techniques, and is referred to as the “LASSO-B²R²” algorithm.

### SUMMARY

An embodiment that is described herein provides an apparatus for sampling signals, including a modulo circuit, an Analog to Digital Converter (ADC) and processing circuitry. The modulo circuit is configured to receive an analog signal, and to derive from the analog signal (i) an analog folded signal whose amplitude is limited to a predefined dynamic range, and (ii) side information indicative of instances in which the analog signal transitions between levels corresponding to odd integer multiples of boundaries specifying the dynamic range. The ADC is configured to sample the analog folded signal to produce a digital folded signal. The processing circuitry is configured to generate a digital unfolded signal, which represents the analog signal both within and outside the dynamic range, based on the digital folded signal and on the side information, and to output the digital unfolded signal.

In some embodiments, the digital unfolded signal has a limited bandwidth depending on a specified oversampling factor, and the processing circuitry is configured to generate a difference folded signal by applying to the digital folded signal a first order difference operation, to calculate for the difference folded signal Discrete Fourier Transform (DFT) bins outside the bandwidth, and to generate the digital unfolded signal based at least on the bins. In other embodiments, the processing circuitry is configured to generate a residual difference signal based at least on the bins, to calculate a residual signal by applying a cumulative sum to the residual difference signal, and to generate the digital unfolded signal by subtracting the residual signal from the digital folded signal. In yet other embodiments, the processing circuitry is configured to round samples of the generated residual difference signal depending on boundaries of the dynamic range, before applying the cumulative sum operation.

In an embodiment, the processing circuitry is configured to calculate nonzero samples of the residual difference signal by applying a matrix-by-vector multiplication operation to a vector containing the bins. In another embodiment, the processing circuitry is configured to derive a partial DFT matrix by selecting, based on the side information, a subset of columns of a full DFT matrix, to calculate from the partial DFT matrix a pseudo-inverse matrix, and to recover the residual difference signal by multiplying the pseudo-inverse matrix by a vector containing the bins. In yet another embodiment, the side information indicates the instances in which the analog signal transitions between the levels using two predefined values.

In some embodiments, the side information is carried by a bit allocated from among bits used by a quantizer of the ADC.

There is additionally provided, in accordance with an embodiment that is described herein, a method for sampling signals, including, receiving an analog signal, and deriving from the analog signal (i) an analog folded signal whose amplitude is limited to a predefined dynamic range, and (ii) side information indicative of instances in which the analog signal transitions between levels corresponding to odd integer multiples of boundaries specifying the dynamic range. The analog folded signal is sampled using an Analog to Digital Converter (ADC), to produce a digital folded signal. A digital unfolded signal, which represents the analog signal both within and outside the dynamic range, is generated based on the digital folded signal and on the side information, and the digital unfolded signal is output.

These and other embodiments will be more fully understood from the following detailed description of the embodiments thereof, taken together with the drawings in which:

### BRIEF DESCRIPTION OF THE DRAWINGS

FIG. 1 is a block diagram that schematically illustrates a modulo sampler, in accordance with an embodiment that is described herein;

FIG. 2A is a diagram that schematically illustrates a signal processed by a modulo operation, in accordance with an embodiment that is described herein;

FIG. 2B is a diagram that schematically illustrates spectral densities of an unfolded signal and of a corresponding residual signal, in accordance with an embodiment that is described herein;

FIGS. 3A-3C are diagrams that schematically illustrate an example folded signal, a corresponding residual signal, and a first order difference of the residual signal, in accordance with embodiments that are described herein;

FIG. 4 is a flow chart that schematically illustrates a method for efficient modulo sampling using level crossing side information, in accordance with an embodiment that is described herein;

FIG. 5 is a flow chart that schematically illustrates a method for recovering an unfolded signal, in accordance with an embodiment that is described herein; and

FIG. 6 is a block diagram that schematically illustrates a modulo and ADC circuit, in accordance with an embodiment that is described herein.

### DETAILED DESCRIPTION OF EMBODIMENTS

### Overview

An Analog to Digital Converter (ADC) typically comprises a sampler that samples an input analog signal, followed by a quantizer that quantizes the samples to be represented digitally by multiple discrete levels.

An ADC is designed for operating in a specified range of amplitudes without causing clipping, also referred to as the “dynamic range” of the ADC. The dynamic range is typically specified by the minimal and maximal amplitudes supported. An analog signal whose amplitude falls outside the dynamic range is clipped by the ADC's quantizer to the minimal and maximal levels.

In principle, to avoid clipping, an ADC with a large enough dynamic range could be used. This solution, however, would be costly and incur high power consumption. In another approach to avoid clipping, a modulo sampler may be used. The modulo sampler applies to the analog signal the non-linear modulo operation that restricts the signal's amplitude to the dynamic range in a nondestructive manner, digitizes the restricted signal using an ADC, and recovers samples of the full range signal from the restricted digitized samples.

Designing a low computational complexity and low sampling rate modulo sampler is challenging. For example, the B²R² algorithm mentioned above is computationally expensive and may not be fast enough in common applications. The complexity of the LASSO-B²R² algorithm mentioned above is typically lower than that of the B²R² algorithm, but the LASSO-B²R² variant is still relatively slow because it requires iterative computations.

Embodiments that are described herein provide methods and circuits for low computational complexity modulo sampler. In the disclosed embodiments, side information indicative of instances in which the analog signal transitions between levels corresponding to odd integer multiples of boundaries specifying the dynamic range. Based on the side information, the samples of the full range signal can be recovered accurately and efficiently using a fast closed-form solution that requires no iterations.

Consider an apparatus for sampling signals, the apparatus includes a modulo circuit, an Analog to Digital Converter (ADC) and processing circuitry. The modulo circuit is configured to receive an analog signal, and to derive from the analog signal (i) an analog folded signal whose amplitude is limited to a predefined dynamic range, and (ii) side information indicative of instances in which the analog signal transitions between levels corresponding to odd integer multiples of boundaries specifying the dynamic range. The ADC is configured to sample the analog folded signal to produce a digital folded signal. The processing circuitry is configured to generate a digital unfolded signal, which represents the analog signal both within and outside the dynamic range, based on the digital folded signal and on the side information, and to output the digital unfolded signal.

In some embodiments, the digital unfolded signal has a limited bandwidth depending on a specified oversampling factor. In such embodiments, the processing circuitry is configured to calculate for a difference folded signal of the digital folded signal, Discrete Fourier Transform (DFT) bins outside the bandwidth, and to generate the digital unfolded signal (indirectly) based at least on the bins. To this end, the processing circuitry generates a residual difference signal based at least on the bins, calculates a residual signal by applying a cumulative sum to the residual difference signal, and generates the digital unfolded signal by subtracting the residual signal from the digital folded signal. In an embodiment, the processing circuitry rounds samples of the generated residual difference signal depending on boundaries of the dynamic range, before applying the cumulative sum operation.

The residual difference signal is a sparse signal comprising a small number of nonzero samples. In some embodiments, the processing circuitry calculates the nonzero samples of the residual difference signal by applying a matrix-by-vector multiplication operation to a vector containing the bins. In an embodiment, the processing circuitry derives a partial DFT matrix by selecting, based on the side information, a subset of columns of a full DFT matrix. The number of remaining columns is small due to the sparsity. The processing circuitry calculates from the partial DFT matrix a pseudo-inverse matrix and multiplies the pseudo-inverse matrix by the vector containing the bins, to recover the residual difference signal.

The side information may be represented in various ways. In an example embodiment the side information comprises a single bit generated by ADC or by the circuit implementing the modulo operation. In some embodiments, to reduce the storage size required for storing the samples output by the ADC, instead of allocating an extra bit, the side information is carried by a bit allocated from among bits used by the quantizer of the ADC.

In the disclosed techniques, an unfolded signal is efficiently recovered from a folded signal using side information indicative of instances in which the analog signal transitions between levels corresponding to odd integer multiples of the dynamic range boundaries. Based on the side information, a close form solution is calculated by performing a matrix-by-vector multiplication operation. The matrix is derived by removing columns from a full DFT matrix based on the side information, and the vector is derived by calculating DFT bins of a difference folded signal in a limited bandwidth. The disclosed modulo sampler has low computational complexity compared to other known modulo samplers.

### System Description

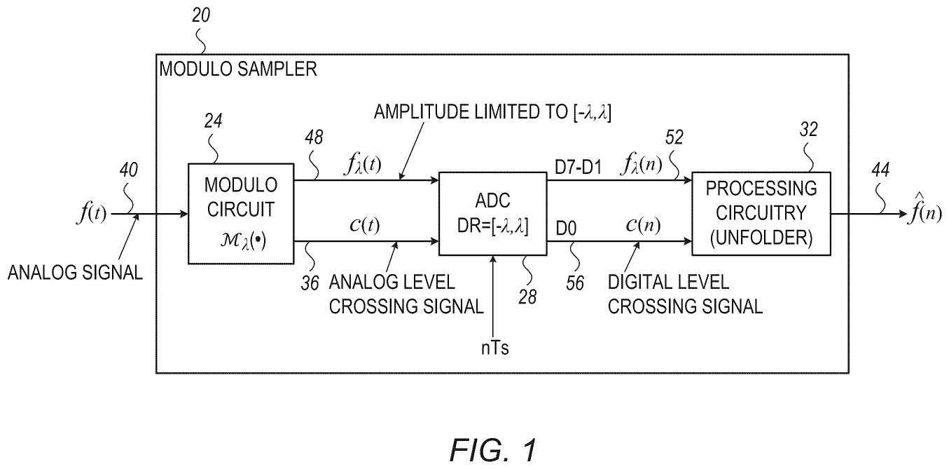

FIG. 1 is a block diagram that schematically illustrates a modulo sampler 20, in accordance with an embodiment that is described herein.

Modulo sampler 20 comprises a modulo circuit 24, an Analog to Digital Converter (ADC) 28 having a dynamic range [−λ, λ], and processing circuitry 32.

Modulo sampler 20 may serve for digitizing analog signals representing physical processes. The analog signal typically comprises an electrical voltage signal or an electrical current signal.

Although the description that follows refers mainly to a symmetric dynamic range, this is not mandatory, and the disclosed embodiments are also applicable to a nonsymmetric dynamic range.

In an end-to-end view, modulo sampler 20 receives an analog signal 40 denoted f(t), and outputs a digital signal 44 denoted \hat{f}(n), which represents a sampled version \hat{f}(nTₛ) of the analog signal, wherein Tₛ denotes the sampling interval and ‘n’ denotes a time index. Samples of the input analog signal may be recovered approximately due to ADC quantization errors and other errors in the underlying circuits. In practice, however, the recovered samples closely resemble the true samples. The signal \hat{f}(n) is also referred to herein as a “digital unfolded signal” or simply “unfolded signal” for brevity. The digital unfolded signal represents the analog signal both within and outside the dynamic range.

To avoid clipping by the ADC, modulo circuit 24 applies to the analog signal f(t) a modulo (warping) operation [symbol] _{λ}(⋅) to produce an analog folded signal 48, denoted f_{λ}(t), whose amplitude is restricted to the dynamic range [−λ, λ]. In the example of FIG. 1, the modulo operation carried out by the modulo circuit is given by:

$${ℳ}_{λ} ( a ) = ( ( a + λ ) mod 2 λ ) - λ \qquad Equation 1$$

The modulo circuit additionally generates an analog level crossing signal 36, indicative of instances in which the amplitude of analog signal 40 transitions between levels corresponding to odd integer multiples of the dynamic range boundaries. The analog level crossing signal indicates the instances in which the analog signal transitions between the levels using two predefined values.

ADC 28 samples and quantizes the analog signal f_{λ}(t) to produce a digital signal 52, denoted f_{λ}(n), which is also referred to herein as a “digital folded signal,” or simply “folded signal” for brevity. The ADC may quantize the signal into a predefined number of discrete quantization levels. For example, an eight-bit ADC quantizes its analog input into 256 quantization levels. In the example of FIG. 1, the ADC outputs toward the processing circuitry a signal comprising eight bits denoted D7 . . . D0, wherein D7-D1 carry the signal f_{λ}(n) and D0 carries a digital level crossing signal c(n), as will be described below.

ADC 28 additionally samples c(t) in synchronization with the sampling instances of the ADC, to generate a digital level crossing signal 56 denoted c(n). The digital level crossing signal is used for efficient recovery of the unfolded signal \hat{f}(n) representing samples of f(t) as will be described below. In some embodiments, c(n) comprises a single bit that replaces the Least Significant Bit (LSB) of the ADC, and is output by the ADC along with the remaining ADC bits. For example, with an eight-bit ADC that outputs data bits D7 . . . D0, the digital level crossing signal replaces D0, and digital folded signal 52 is carried over the D7 . . . D1 bits.

Although in FIG. 1, the digital level crossing signal is generated by the ADC, in alternative embodiments the digital level crossing signal may be generated within the modulo circuit and provided directly to the processing circuitry. In such embodiments, the modulo circuit is synchronized to the sampling instances of the ADC.

The folded signal f_{λ}(n) may be decomposed as given by:

$${f}_{λ} ( n ) = \hat{f} ( n ) + z ( n ) \qquad Equation 2$$

wherein the samples of the signal z(n) get values that are integer multiples of 2λ, i.e., 2λ [symbol] . The signal z(n) is also referred to herein as a “residual signal”. In accordance with Equation 2, the unfolded signal f(n) corresponding to the analog signal f(t) may be recovered from the samples of the folded signal f_{λ}(n), given the residual signal z(n). In some embodiments, a recovery scheme for recovering the unfolded signal focuses on recovering the residual signal.

Processing circuitry 32, also referred to herein as an “unfolder” module, efficiently recovers the residual signal z(n) based on (i) the folded signal f_{λ}(n) and (ii) digital level crossing signal 56. In some embodiments, based on the decomposition presented in Equation 2, The processing circuitry 32 recovers the unfolded signal as given by:

$$\hat{f} ( n ) = {f}_{λ} ( n ) - z ( n ) \qquad Equation 3$$

Methods for recovering the residual signal and the unfolded signal will be described in detail below.

The configuration of modulo sampler 20 in FIG. 1, including the configurations of modulo circuit 24, ADC 28 and unfolder 32, are example configurations, which are chosen purely for the sake of conceptual clarity. In alternative embodiments, any modulo sampler, modulo circuit, ADC and unfolder configurations can also be used. The different elements of modulo sampler 20 may be implemented in hardware, such as using one or more Application-Specific Integrated Circuits (ASICs) or Field-Programmable Gate Arrays (FPGAs). In alternative embodiments, some elements of modulo sampler 20, e.g., the unfolder functionality (implemented by processing circuitry 32) may be implemented in software executing on a suitable processor, or using a combination of hardware and software elements.

Elements that are not necessary for understanding the principles of the present application, such as various interfaces, addressing circuits, timing and sequencing circuits and debugging circuits, have been omitted from FIG. 1 for clarity.

In some embodiments, processing circuitry 32 may comprise a general-purpose processor, which is programmed in software to carry out the unfolder functions described herein. The software may be downloaded to the processor in electronic form, over a network, for example, or it may, alternatively or additionally, be provided and/or stored on non-transitory tangible media, such as magnetic, optical, or electronic memory.

Although in the Example of FIG. 1 modulo circuit 24 ADC 28 and processing circuitry 32 are implemented on separated chips, this is not mandatory. In alternative embodiments at least two of the modulo circuit, ADC and processing circuitry may be implemented as interconnected dies on a common chip.

An example hardware implementation of the modulo operation in modulo circuit 24 is described, for example, in a paper entitled “A hardware prototype of wideband high-dynamic range analog-to-digital converter,” The Institute of Engineering and Technology (IET), Volume 17, Issue 4, July 2023, pages 181-192, which is incorporated herein by reference.

Generating the analog level crossing signal 36 by the modulo circuit may be implemented using two comparators (for the respective lower and upper boundaries of the dynamic range) for comparing between the analog signal and crossing levels corresponding to odd integer multiples of the dynamic range boundaries.

### Mathematical Introduction

In this section mathematical formulations are described as a basis for describing embodiments for recovering an unfolded signal from a corresponding folded signal.

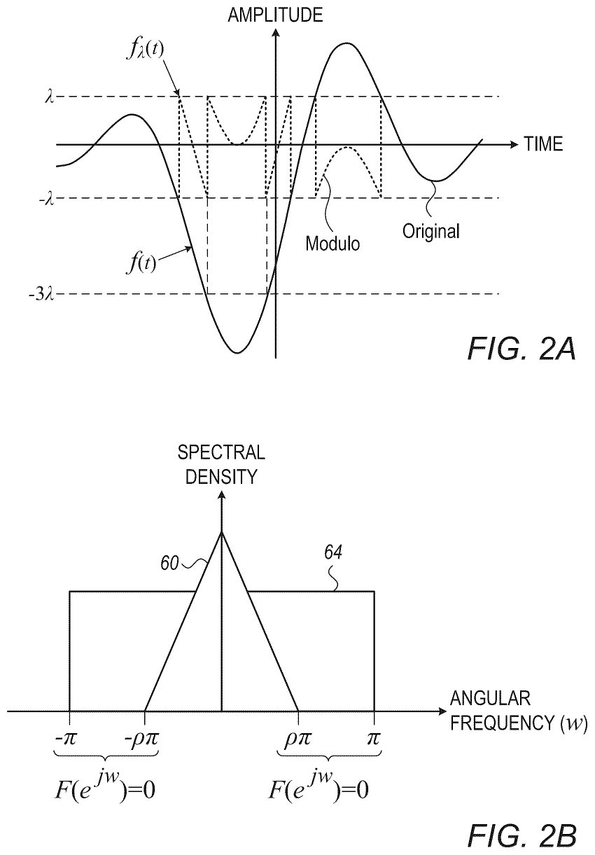

FIG. 2A is a diagram that schematically illustrates a signal processed by a modulo operation, in accordance with an embodiment that is described herein.

As noted above, f(t) denotes the analog signal (40) input to modulo sampler 20, and f_{λ}(t) denotes the analog signal 48 derived from f(t) by applying a modulo operation of, e.g., as given by Equation 1 above. As shown in the figure, parts of the input signal that fall above the boundary λ or below the boundary −λ are wrapped and are thus restricted to the dynamic range. In the present example, the signal amplitude goes below −3λ, resulting in another folding. In general, wrapping occurs when the analog signal crosses levels that are odd integer multiples of λ, i.e., (2 [symbol] +1)λ

FIG. 2B is a diagram that schematically illustrates spectral densities (60 and 64) of an unfolded signal and of a corresponding residual signal, in accordance with an embodiment that is described herein.

Let Tₛ denote the sampling interval used for sampling the signal f_{λ}(t) by ADC 28. The corresponding sampling rate Wₛ (in Rad/Second) is given by:

$${w}_{s} = \frac{2 π}{{T}_{s}} = OF \cdot ( 2 {w}_{m} ) \qquad Equation 4$$

wherein OF>1 denotes the oversampling factor and 2wₘ denotes the Nyquist rate. Using these notations, the bandwidth of \hat{f}(n) is limited to the frequency range [−ρπ, ρπ], wherein ρ is given by:

$$ρ = \frac{2 {w}_{m}}{{w}_{s}} = \frac{1}{OF} \qquad Equation 5$$

Taking a Fourier transform on both sides of Equation 2 results in:

$${F}_{λ} ( {e}^{jw} ) = \hat{F} ( {e}^{jw} ) + Z ( {e}^{jw} ) \qquad Equation 6$$

wherein F_{λ}, \hat{F} and Z denote the Fourier transforms of f_{λ}(n), \hat{f}(n) and z(n), respectively.

Let B denote the frequency range B=(−λ,−ρπ)∪(ρπ, π). Since F(e^{jw})=0 in B, the equality F_{λ}(e^{jw})=Z(e^{jw}) also holds in B. In principle, by increasing the oversampling factor, the range of B increases, which increases the amount of information available for signal recovery. On the other hand, however, small OF values are typically desirable for reducing cost and power consumption. It is noted that a frequency range in which the spectral density equals zero means in practice that the underlying signal is highly attenuated in this frequency range compared to other frequency ranges.

Applying a first order difference operation to both sides of Equation 2 results in:

$${\tilde{f}}_{λ} ( n ) = \tilde{f} ( n ) + \tilde{z} ( n ) \qquad Equation 7$$

wherein the underlying first order difference operation calculates difference samples between consecutive samples of the relevant signal. Transforming the expression in Equation 7 to the frequency domain using the Fourier transform, results in:

$${\tilde{F}}_{λ} ( {e}^{jw} ) = \tilde{F} ( {e}^{jw} ) + \tilde{Z} ( {e}^{jw} ) \qquad Equation 8$$

It is noted that similarly to f_{λ}(n), the difference signal \tilde{f}_{λ}(n) in Equation 7 is also band limited to B, and therefore the equality \tilde{F}_{λ}(e^{jw})=\tilde{Z}(e^{jw}) also holds in B. As will be described in detail below, \tilde{z}(n) can be recovered efficiently by evaluating bins of a Discrete Fourier Transform (DFT) of \tilde{f}_{λ}(n) in B.

### Example Time Domain Signals

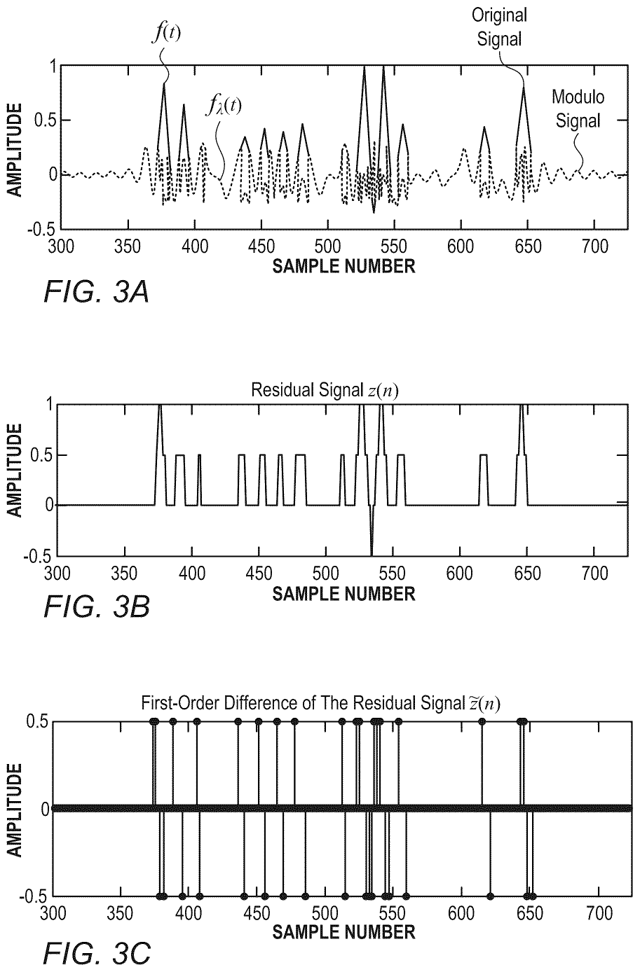

FIGS. 3A-3C are diagrams that schematically illustrate an example folded signal, a corresponding residual signal, and a first order difference of the residual signal, in accordance with embodiments that are described herein. In this example, the amplitude of f(t) is between −1 and 1, and λ=0.25.

FIG. 3A depicts a signal f(t) input to modulo sampler 20 and a corresponding signal f_{λ}(t) output by modulo circuit 24. As shown in the figure, the output of the modulo circuit is confined to the dynamic range of ADC 28.

FIG. 3B depicts a residual signal z(n) satisfying the expression in Equation 2. In the present example, the residual signal gets values, −λ1, 0, 2λ and 4λ. The digital level crossing signal c(n) (not shown) gets a binary value ‘1’ when the value of the residual signal transitions between consecutive samples i.e., z(n)≠z(n−1), and gets a value ‘0’ when z(n) equals z(n−1).

FIG. 3C depicts a residual difference signal \tilde{z}(n) generated by applying a first order difference operation to the residual signal of FIG. 3B. In this example, the residual difference signal gets values −2λ, 0 and 2λ. As shown in the figure, the residual difference signal is sparse, i.e., contains a much larger number of zero samples compared to the number of nonzero samples.

It is noted that in general the digital level crossing signal c(n) and the residual difference signal z(n) get nonzero values in the same instances.

### Efficient Methods for Modulo Sampling

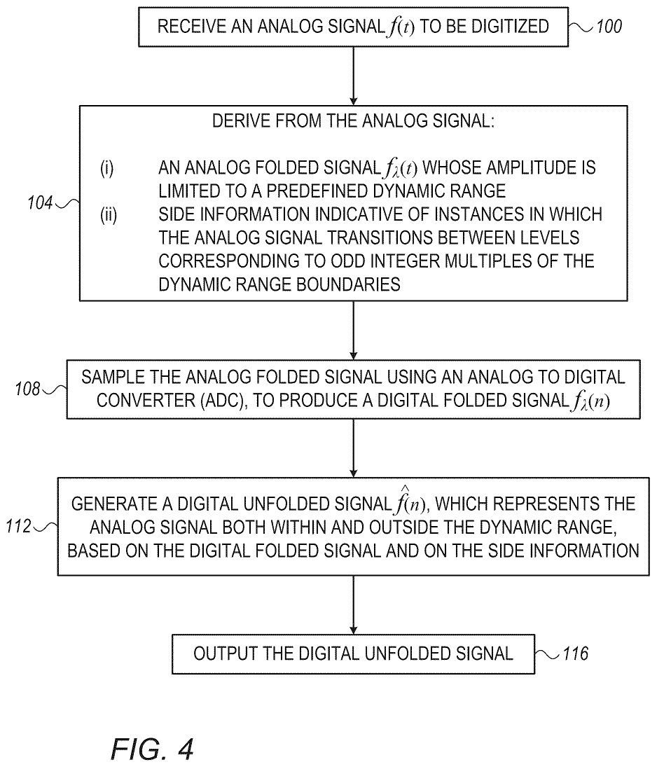

FIG. 4 is a flow chart that schematically illustrates a method for efficient modulo sampling using level crossing side information, in accordance with an embodiment that is described herein.

The method will be described as executed by elements of modulo sampler 20 of FIG. 1.

The method begins with modulo sampler 20 receiving and analog signal f(t) to be digitized, at a signal reception step 100. At a modulo calculation step 104, modulo circuit 24 derives from the received analog signal (i) an analog folded signal f_{λ}(t) whose amplitude is limited to a predefined dynamic range (of ADC 28), and (ii) side information indicative of instances in which the analog signal transitions between levels corresponding to odd integer multiples of the dynamic range boundaries.

At a sampling step 108, ADC 28 samples the analog folded signal to produce a digital folded signal f_{λ}(n). At an unfolding step 112, unfolder 32 generates a digital unfolded signal \hat{f}(n) based on the digital folded signal and on the side information. The digital unfolded signal represents the received analog signal both within and outside the dynamic range. The side information enables the unfolder to recover the digital unfolded signal using a low computational complexity closed form solution, as will be described below. At an outputting step 116, the modulo sampler outputs the digital unfolded signal, and the method terminates.

### Methods for Recovery of an Unfolded Signal

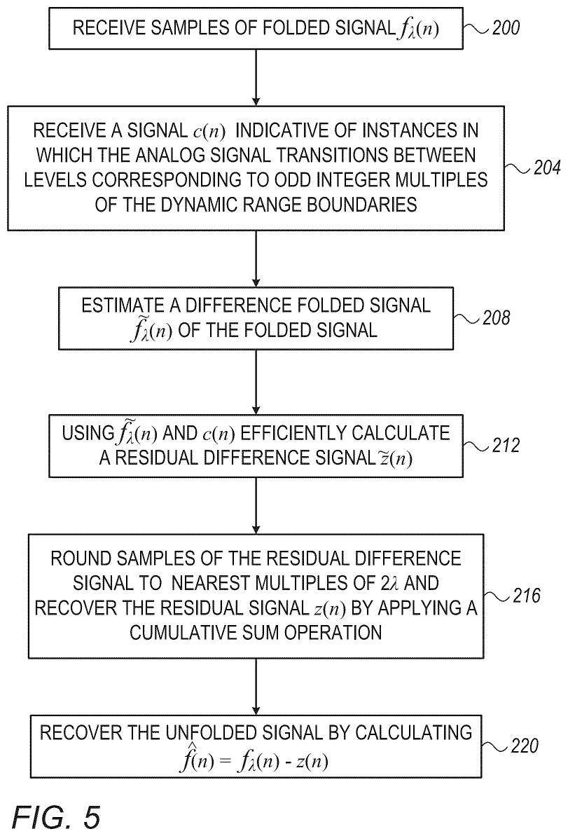

FIG. 5 is a flow chart that schematically illustrates a method for recovering an unfolded signal, in accordance with an embodiment that is described herein. The method can be used for implementing step 112 of the method of FIG. 4. The method will be described as executed by unfolder 32 of FIG. 1.

The method begins with unfolder 32 receiving samples of a folded signal f_{λ}(n), from ADC 28, at a folded signal reception step 200. At a side information reception step 204, the unfolder receives side information from the ADC (or from modulo circuit 24). In the present example, the side information comprises digital level crossing signal 56 c(n), wherein c(n) is indicative of instances in which the input signal f(t) transitions between levels corresponding to odd integer multiples of the dynamic range boundaries −λ and λ within the sampling interval [nTₛ, (n+1)Tₛ]. The digital level crossing signal gets a binary value c(n)=1 when a transition occurs, and gets a binary value c(n)=0, otherwise.

At a folded difference step 208, the unfolder estimates a difference folded signal \tilde{f}_{λ}(n) from the folded signal of step 200. At a residual signal recovery 212, the unfolder efficiently recovers the residual difference signal \tilde{z}(n) based on the folded signal of step 208 and on the digital level crossing signal c(n) of step 204. Step 212 will be described in detail below.

At a residual signal recovery step 216, the unfolder recovers the residual signal z(n) by rounding the samples of the residual difference signal to the nearest integer multiples of 2λ, and applying to the rounded samples a cumulative sum operation. At an unfolded signal recovery step 220, the unfolder recovers the unfolded signal f (n) by subtracting the residual signal z(n) recovered at step 216 from the folded signal f_{λ}(n) of step 200, as given in Equation 3. Following step 220 the method terminates.

Next, step 212 of the method of FIG. 5 is described in detail. The Discrete Fourier Transform (DFT) of \tilde{z}(n) in B can be written as:

$${\tilde{F}}_{λ} ( {e}^{\frac{j 2 π k}{N}} ) = {\sum }_{n = 0}^{N - 1} \tilde{z} ( n ) {e}^{\frac{- j 2 π kn}{N}} , \frac{2 π k}{N} ϵ ( ρπ , 2 π - ρπ ) \qquad Equation 9$$

Equation 9 can be re-written in matrix form as given by:

$${[ {\tilde{F}}_{λ} ]}_{M \times 1} = {{[ V ]}_{M \times N} [ \tilde{Z} ]}_{N \times 1} \qquad Equation 10$$

In Equation 10, the number of rows M (M<N) equals the number of discrete frequencies

$$\frac{2 π k}{N}$$

that belong to the frequency range (ρπ, 2π−ρπ). The matrix V denotes a full DFT matrix whose elements are given by:

$${V}_{k , n} = {e}^{\frac{- j 2 π kn}{N}} \qquad Equation 11$$

Let [Δz]_{N×1} denote the vector comprising elements of the residual difference signal \tilde{z}(n). Let S denote a set of time indices for which Δz(n) is nonzero, and let S^{c} denote a complementary set of indices for which Δz(n)=0. In some embodiments, unfolder 32 derives S from the digital level crossing signal c(n) (56). In an embodiment, based on c(n) (or S) the unfolder derives a vector Δzₛ, which is an |S|×1 vector containing the nonzero elements in Δz. Due the sparsity of Δz, |S| is much smaller than N.

The unfolder constructs a partial DFT matrix Vₛ containing the |S| columns in V corresponding to the indices in S. Again, the number of columns in Vₛ is much smaller than in V. Using these notations, Equation 10 can be rewritten as:

$${[ {\tilde{F}}_{λ} ]}_{M \times 1} = {{[ Vs ]}_{M \times \vert S \vert} [ {Δ z}_{S} ]}_{\vert S \vert \times 1} \qquad Equation 12$$

The unfolder solves Equation 12 for calculating Δzₛ as a closed form solution as described herein. The unfolder calculates \tilde{F}_{λ} by applying a DFT to f_{λ}(n) in B=(−π,−ρπ)∪(ρπ, π). Based on Vₛ the unfolder calculates a pseudo-invers matrix

$${V}_{S}^{}$$

given by:

$${V}_{S}^{} = {( {V}_{S}^{H} {V}_{S} )}^{- 1} {V}_{S}^{H} \qquad Equation 13$$

and calculates the vector Δzₛ as given by:

$${Δ z}_{S} = {V}_{S}^{} \tilde{{F}_{λ}} \qquad Equation 14$$

Using the indices in S, the unfolder reconstructs the full difference signal \tilde{z}(n) from Δzₛ of Equation 14 and from the zeros indicated by S^{c}, which concludes step 212.

The embodiments described above are given by way of example, and other suitable embodiments can also be used. For example, although in the embodiments described above a DFT has been used, other suitable time-frequency transforms can also be used. For example, the orthogonal complex conjugate periodic transform can be used, which is described, for example, in “Orthogonal and Non-Orthogonal Signal Representations Using New Transformation Matrices Having NPM Structure,” IEEE Transactions on Signal Processing, volume 68, Feb. 6, 2020.

In the embodiments described above the analog and digital level crossing signals are indicative of instances in which the analog signal transitions between levels corresponding to odd integer multiples of the dynamic range boundaries. Alternatively, the levels may correspond to boundaries of the dynamic range and of shifted versions of the dynamic range.

### Example Modulo and ADC Circuit Implementation

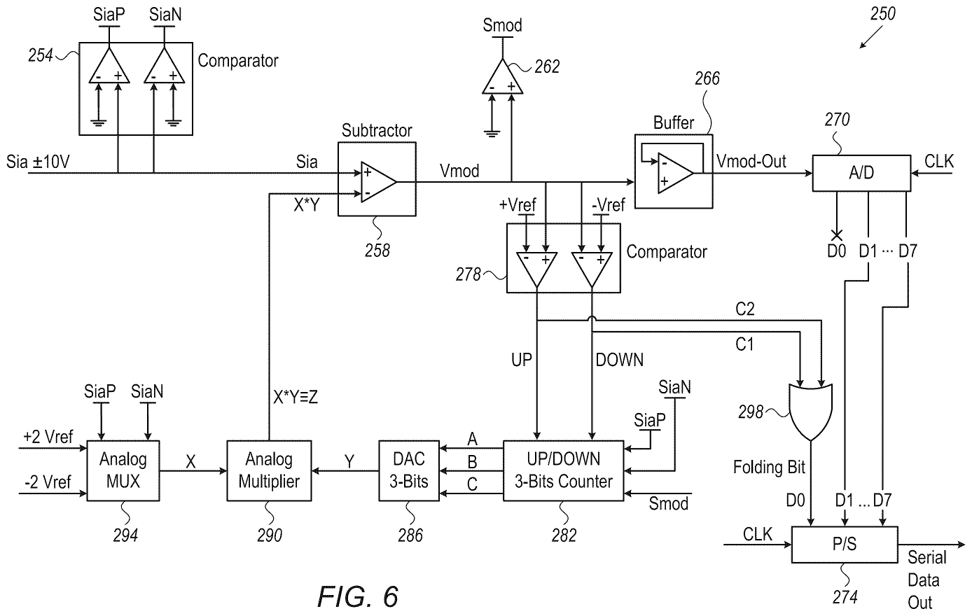

FIG. 6 is a block diagram that schematically illustrates a modulo and ADC circuit 250, in accordance with an embodiment that is described herein. Circuit 250 can be used, for example, for implementing modulo circuit 24 and ADC 28 of FIG. 1 above. Aspects of such a circuit are also addressed by Shah et al., in “Compressed Sensing Based Residual Recovery Algorithms and Hardware for Modulo Sampling,” arXiv:2412.12724, Dec. 17, 2024, which is incorporated herein by reference. See also the article “A hardware prototype of wideband high-dynamic range analog-to-digital converter,” cited above.

The analog input signal digitized by circuit 250 is denoted Sia (top left of FIG. 6). Circuit 250 folds this signal into the dynamic range [−λ, λ], and digitizes the folded signal using an ADC 270. In addition, circuit 250 generates a single “folding bit” that is subsequently used as side information for reconstruction. The Least-Significant Bit (LSB) of ADC 270, denoted D0, is discarded and its place is reused for outputting the folding bit along with the remaining seven Most-Significant Bits (MSBs) denoted D1-D7. In the present example, the original range of the signal is ±10V. The folded signal occupies the range [−1.25V,+1.25V], i.e., λ=1.25V.

A comparator 254 generates two signals denoted SiaP and SiaN, which indicate the sign of the analog input signal SiA (SiaP is “1” when Sia has a positive voltage and “0” when Sia has a negative voltage; SiaN is “1” when Sia has a negative voltage and “0” when Sia has a positive voltage).

A subtractor 258 subtracts a value denoted Z from Sia, to produce a folded signal denoted Vmod. The derivation of Z is described in detail below. A comparator 262 generates a signal denoted Smod, which indicates the sign of the folded signa; Vmod (Smod is “1” when Vmod has a positive voltage and “0” when Vmod has a negative voltage).

A buffer 266 buffers the signal Vmod. The output of buffer 266 is provided to ADC 270 for digitization. ADC 270 outputs a digital signal comprising a stream of eight-bit samples denoted [D0 . . . D7]. The seven MSBs [D1 . . . D7] are provided to a Parallel-to-Serial converter (P/S) 274. In addition, a folding bit is provided to P/S 274 instead of the LSB produced by ADC 270. The seven MSBs of the digital signal, and the folding bit occupying D0, are provided as a serial data output of circuit 250. This serial data output can be used for reconstructing the analog input signal Sia using the techniques described above, e.g., by circuitry 32 of FIG. 1.

The remaining part of circuit 250, described below, produces the folding bit.

In the present example, a comparator 278 compares the folded signal Vmod to a pair of reference signals denoted +Vref and −Vref, so as to produce two signals denoted UP and DOWN, respectively. Vref is set to be A, in the present example 1.25V. Signal UP becomes “1” when folded signal Vmod exceeds +Vref Signal DOWN becomes “1” when folded signal Vmod falls below −Vref.

A 3-bit up/down counter 282 receives signals UP and DOWN as input. Up/down counter 282 also receives as input signals SiaP and SiaN (indicating the sign of the original analog input signal Sia) and signal Smod (indicating the sign of the folded signal Vmod. Counter 282 outputs a three-bit counter value denoted [A,B,C]. The counter value indicates by how many multiples of 2λ the input signal should be folded in order to bring it into the range [−λ, λ].

A 3-bit Digital-to-Analog Converter (DAC) 286 converts the counter value [A,B,C] into an analog value denoted Y. In parallel, an analog multiplexer (MUX) 294 outputs an analog value denoted X from +Vref, −Vref, SiaP and SiaN. The value X is either +Vref or −Vref (either 2·1.25V or −2·1.25V in the present example), depending on whether folding should be performed upwards or downwards (as indicated by SiaP and SiaN).

An analog multiplier 290 multiplies the two values X and Y, yielding value Z. As noted above, Z is subtracted from the analog input signal SiA to produce Vmod.

To generate the folding bit, an OR gate 298 output the logical OR between the UP and DOWN outputs of comparator 278. Whenever either UP or DOWN is “1”, a folding operation has occurred and the folding bit should be set to “1”. When both UP and DOWN are “0”, signal Vmod is within the desired range of ±λ, and the folding bit should be “0”. The folding bit is provided as LSB DO to P/S 274, for outputting as part of the serial data.

It will be appreciated that the embodiments described above are cited by way of example, and that the following claims are not limited to what has been particularly shown and described hereinabove. Rather, the scope includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An apparatus for sampling signals, comprising:
a modulo circuit, configured to receive an analog signal, and to derive from the analog signal (i) an analog folded signal whose amplitude is limited to a predefined dynamic range, and (ii) side information consisting of a single bit indicative of instances in which the analog signal transitions between levels corresponding to odd integer multiples of boundaries specifying the dynamic range;
an Analog to Digital Converter (ADC), configured to sample the analog folded signal to produce a digital folded signal; and
processing circuitry, configured to:
generate a digital unfolded signal, which represents the analog signal both within and outside the dynamic range, based on the digital folded signal and on the side information; and
output the digital unfolded signal.

2. The apparatus according to claim 1, wherein the digital unfolded signal has a limited bandwidth depending on a specified oversampling factor, and wherein the processing circuitry is configured to generate a difference folded signal by applying to the digital folded signal a first order difference operation, to calculate for the difference folded signal Discrete Fourier Transform (DFT) bins outside the bandwidth, and to generate the digital unfolded signal based at least on the bins.

3. The apparatus according to claim 2, wherein the processing circuitry is configured to generate a residual difference signal based at least on the bins, to calculate a residual signal by applying a cumulative sum to the residual difference signal, and to generate the digital unfolded signal by subtracting the residual signal from the digital folded signal.

4. The apparatus according to claim 3, wherein the processing circuitry is configured to round samples of the generated residual difference signal depending on boundaries of the dynamic range, before applying the cumulative sum operation.

5. The apparatus according to claim 3, wherein the processing circuitry is configured to calculate nonzero samples of the residual difference signal by applying a matrix-by-vector multiplication operation to a vector containing the bins.

6. The apparatus according to claim 3, wherein the processing circuitry is configured to derive a partial DFT matrix by selecting, based on the side information, a subset of columns of a full DFT matrix, to calculate from the partial DFT matrix a pseudo-inverse matrix, and to recover the residual difference signal by multiplying the pseudo-inverse matrix by a vector containing the bins.

7. The apparatus according to claim 1, wherein the side information indicates the instances in which the analog signal transitions between the levels using two predefined values.

8. The apparatus according to claim 1, wherein the single bit is allocated from among bits used by a quantizer of the ADC.

9. A method for sampling signals, comprising:
receiving an analog signal, and deriving from the analog signal (i) an analog folded signal whose amplitude is limited to a predefined dynamic range, and (ii) side information consisting of a single bit indicative of instances in which the analog signal transitions between levels corresponding to odd integer multiples of boundaries specifying the dynamic range;
sampling the analog folded signal using an Analog to Digital Converter (ADC), to produce a digital folded signal;
generating a digital unfolded signal, which represents the analog signal both within and outside the dynamic range, based on the digital folded signal and on the side information; and
outputting the digital unfolded signal.

10. The method according to claim 9, wherein the digital unfolded signal has a limited bandwidth depending on a specified oversampling factor, and comprising generating a difference folded signal by applying to the digital folded signal a first order difference operation, calculating for the difference folded signal Discrete Fourier Transform (DFT) bins outside the bandwidth, and generating the digital unfolded signal based at least on the bins.

11. The method according to claim 10, and comprising generating a residual difference signal based at least on the bins, calculating a residual signal by applying a cumulative sum to the residual difference signal, and generating the digital unfolded signal by subtracting the residual signal from the digital folded signal.

12. The method according to claim 11, and comprising rounding samples of the generated residual difference signal depending on boundaries of the dynamic range, before applying the cumulative sum operation.

13. The method according to claim 11, and comprising calculating nonzero samples of the residual difference signal by applying a matrix-by-vector multiplication operation to a vector containing the bins.

14. The method according to claim 11, wherein generating a residual difference signal comprises deriving a partial DFT matrix by selecting, based on the side information, a subset of columns of a full DFT matrix, calculating from the partial DFT matrix a pseudo-inverse matrix, and recovering the residual difference signal by multiplying the pseudo-inverse matrix by a vector containing the bins.

15. The method according to claim 9, wherein the side information indicates the instances in which the analog signal transitions between the levels using two predefined values.

16. The method according to claim 9, wherein the single bit is allocated from among bits used by a quantizer of the ADC.
